(19) United States
(12) Patent Application Publication
(10) Pub. No.: US 2023/0369183 A1
(43) Pub. Date: Nov. 16, 2023

(54) SEMICONDUCTOR APPARATUS AND METHOD FOR MANUFACTURING SEMICONDUCTOR APPARATUS

(71) Applicant: FUJI ELECTRIC CO., LTD., Kawasaki-shi (JP)

(72) Inventor: Yoshihiko KAWAKAMI, Kawasaki-shi (JP)

(73) Assignee: FUJI ELECTRIC CO., LTD., Kawasaki-shi (JP)

(21) Appl. No.: 18/184,413

(22) Filed: Mar. 15, 2023

(30) Foreign Application Priority Data
May 16, 2022 (JP) 2022-080194

(51) Int. Cl. H01L 23/495; H01L 23/00

(52) U.S. Cl. CPC H01L 23/49548; H01L 24/40; H01L 2224/40247

(57) ABSTRACT

A semiconductor apparatus includes an insulating substrate having a circuit board electrically connected to a semiconductor device, and a terminal member having a main terminal and a connection terminal bonded to the circuit board. The connection terminal has at least one distal end portion bonded to the circuit board, a main body portion that rises from the at least one distal end portion and extends toward the main terminal, and a coupling portion having a conductive property and being coupled to the main body portion. The main body portion has a main body coupling portion to which the coupling portion is coupled. A cross-sectional area of the coupling portion perpendicular to a direction in which a current flows in the coupling portion is larger than a cross-sectional area of a main body coupling portion perpendicular to a direction in which a current flows in the main body coupling portion.

### CROSS REFERENCE TO RELATED APPLICATIONS

This application is based upon and claims the benefit of priority of the prior Japanese Patent Application No. 2022-080194, filed on May 16, 2022, the entire contents of which are incorporated herein by reference.

### BACKGROUND OF THE INVENTION

### Field of the Invention

The present invention relates to a semiconductor apparatus and a method for manufacturing the same.

### Description of the Related Art

A semiconductor apparatus has a substrate provided with a semiconductor device such as an IGBT (insulated gate bipolar transistor), a power MOSFET (metal oxide semiconductor field effect transistor), or an FWD (free wheeling diode), and is used for an inverter apparatus or the like (see, e.g., International Publication No. WO 2021/100199 and Japanese Patent Laid-Open Nos. 2019-140320 and 2013-197560).

In this type of semiconductor apparatus, there has been proposed a semiconductor apparatus having a bonding body in which a terminal to be electrically connected to an insulating substrate having a semiconductor device arranged thereon is bonded to a circuit pattern of the insulating substrate by a bonding layer, and a support body that holds a distance between the bonding body and the circuit pattern to interpose the bonding layer therebetween (see, e.g., International Publication No. WO 2021/100199).

### SUMMARY OF THE INVENTION

A power semiconductor apparatus has respective output terminals in UVW phases to drive a three-phase motor. The power semiconductor apparatus has a PN terminal for each of the phases to be connected to a main circuit capacitor.

Connection terminals to be connected to the inside of the apparatus from the output terminals in the U, V, and W phases and the respective PN terminals in the phases are bonded, for example by ultrasonic connection, to an insulating substrate to which front and back Cu foils each having an IGBT or the like mounted thereon are attached.

The connection terminals are bonded to the insulating substrate in a narrow space with recent requests to reduce the semiconductor apparatus in size and thickness. Accordingly, the connection terminal itself decreases in size, and easily generates heat. A thermal stress caused by heat generation may result in deterioration in reliability of the semiconductor apparatus.

As described above, a terminal including a bonding body to be bonded to a circuit pattern by a bonding layer and a support body that holds a distance between the bonding body and the circuit pattern is formed by punching processing and bending processing. Accordingly, even if the support body functions as a part of a heat dissipation path, a configuration in which the volume of the terminal itself is positively increased has not been adopted. Therefore, the thermal capacity of the terminal cannot be increased.

The present invention is directed to providing a semiconductor apparatus capable of preventing, in a terminal member having a main terminal connectable to an external conductor and a connection terminal to be bonded to a circuit board, the connection terminal from generating heat and a method for manufacturing the semiconductor apparatus.

In an aspect of the present invention, a semiconductor apparatus includes a semiconductor device, an insulating substrate having a circuit board to be electrically connected to the semiconductor device, and a terminal member. The terminal member has a main terminal connectable to an external conductor and a connection terminal to be bonded to the circuit board. The connection terminal has a distal end portion to be bonded to the circuit board, a main body portion that rises from the distal end portion and extends toward the main terminal, and a coupling portion having a conductive property and coupled to the main body portion. The coupling portion has a larger cross-sectional area perpendicular to a current path than that of a portion, to which the coupling portion is coupled, of the main body portion.

According to the aspect of the present invention, it is possible to prevent, in a terminal member having a main terminal connectable to an external conductor and a connection terminal to be bonded to a circuit board, the connection terminal from generating heat.

### BRIEF DESCRIPTION OF DRAWINGS

FIG. 1 is a plan view illustrating a semiconductor apparatus according to an embodiment;

FIG. 2 is a right side view illustrating a connection terminal according to the embodiment;

FIG. 3 is a plan view illustrating the connection terminal according to the embodiment;

FIG. 4 is a right side view illustrating a connection terminal according to a first modification of the embodiment;

FIG. 5 is a plan view illustrating the connection terminal according to the first modification of the embodiment;

FIG. 6 is a right side view illustrating a connection terminal according to a second modification of the embodiment;

FIG. 7 is a plan view illustrating the connection terminal according to the second modification of the embodiment;

FIG. 8 is a right side view illustrating a connection terminal according to a third modification of the embodiment; and

FIG. 9 is a plan view illustrating a connection terminal according to a fourth modification of the embodiment.

### DESCRIPTION OF EMBODIMENTS

A semiconductor apparatus according to an embodiment of the present invention and a method for manufacturing the same will be described below with reference to the drawings. The present invention is not limited to the embodiment described below, and can be implemented by appropriate deformation without departing from the scope of the invention.

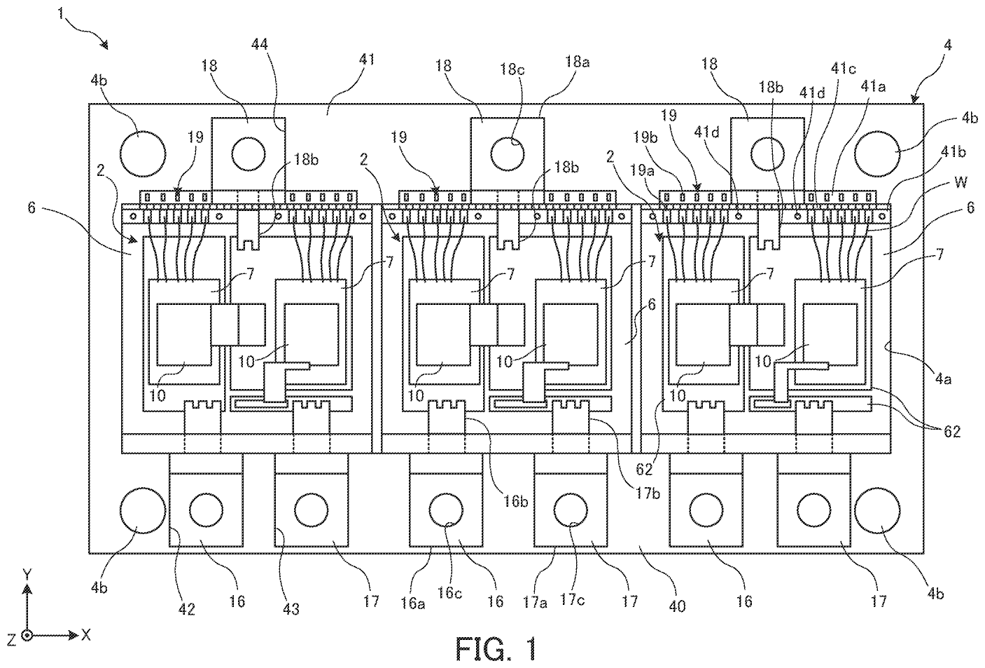

FIG. 1 is a plan view illustrating a semiconductor apparatus 1 according to an embodiment.

In FIG. 1 and FIGS. 2 to 9, described below, a longitudinal direction of the semiconductor apparatus 1, a transverse direction of the semiconductor apparatus 1, and a height direction (a thickness direction of a substrate) are respectively defined as an X-direction, a Y-direction, and a Z-direction. The longitudinal direction of the semiconductor apparatus 1 represents a direction in which a plurality of semiconductor modules (unit modules) are arranged. X-, Y-, and Z-axes as illustrated are perpendicular to one another, to constitute a right-handed system. In some cases, the X-direction, the Y-direction, and the Z-direction may be respectively referred to as a left-right direction, a front-rear direction, and an up-down direction. The directions (front-rear, left-right, and up-down directions) are phrases used for convenience of illustration, and a correspondence with each of the X-, Y-, and Z-directions may change depending on an attachment posture of the semiconductor apparatus 1. For example, the heat dissipation surface side (cooler side) of the semiconductor apparatus 1 and the opposite side thereof are respectively referred to as the lower surface side and the upper surface side. In this specification, a planar view means a case where an upper surface or a lower surface of the semiconductor apparatus is viewed in the Z-direction.

The semiconductor apparatus 1 according to the present embodiment is a power semiconductor module that is applied to a power conversion apparatus such as a power control unit, for example, and constitutes an inverter circuit.

The semiconductor apparatus 1 illustrated in FIG. 1 includes a plurality of (three in the present embodiment) unit modules 2, a cooler (not illustrated) that cools the unit modules 2, a case member 4 that houses the plurality of unit modules 2, and sealing resin (not illustrated) to be injected into the case member 4.

Each of the unit modules 2 includes an insulating substrate 6 and a semiconductor device 7 arranged on the insulating substrate 6. In the present embodiment, the three unit modules 2 are arranged side by side in the X-direction. The three unit modules 2 respectively constitute a U phase, a V phase, and a W phase, for example, and form a three-phase inverter circuit as a whole. The unit module 2 may also be referred to as a power cell or a semiconductor unit.

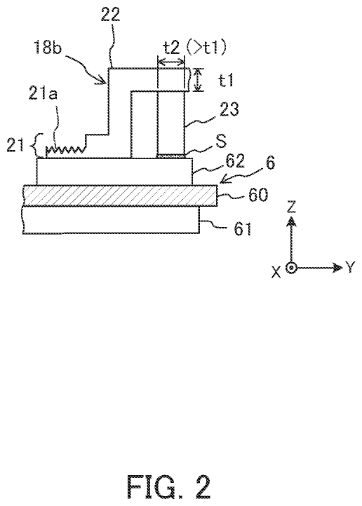

The insulating substrate 6 illustrated in FIG. 2 is composed of a DCB (direct copper bonding) substrate, an AMB (active metal brazing) substrate, or a metal base substrate, for example. For example, the insulating substrate 6 has an insulating plate 60, a heat dissipation plate 61 arranged on a lower surface of the insulating plate 60, and a plurality of circuit boards 62 arranged on an upper surface of the insulating plate 60. The insulating substrate 6 is formed into a rectangular shape in a planar view, for example.

The insulating plate 60 is formed of an insulating material such as a ceramic material such as alumina (Al₂O₃), aluminum nitride (AlN), or silicon nitride (Si₃N₄), a resin material such as epoxy, or an epoxy resin material using a ceramic material as a filler. The insulating plate 60 may also be referred to as an insulating layer or an insulating film.

The heat dissipation plate 61 has a predetermined thickness in the Z-direction, and is formed to cover the lower surface of the insulating plate 60. The heat dissipation plate 61 is formed of a metal plate having a good thermal conductivity such as copper or aluminum.

The plurality of circuit boards 62 are formed on the upper surface of the insulating plate 60. Any number of (one or more) circuit boards 62 may be formed on the upper surface of insulating plate 60. The circuit boards 62 are each a metal layer such as a copper foil and are formed into island shapes while being electrically insulated from one another on the insulating plate 60. The circuit board 62 may also be referred to as a circuit layer.

As illustrated in FIG. 1, the semiconductor device 7 is arranged on an upper surface of the insulating substrate 6 (the circuit board 62) with a bonding material such as a solder (not illustrated) interposed therebetween. Although two semiconductor devices 7 are illustrated for one insulating substrate 6 for convenience of illustration in FIG. 1, more semiconductor devices 7 may be arranged on the insulating substrate 6. The semiconductor device 7 is formed into a square shape or a rectangular shape in a planar view with a semiconductor substrate formed of silicon (Si), silicon carbide (SiC), gallium nitride (GaN), and diamond, for example.

A switching element such as an IGBT or a power MOSFET or a diode such as an FWD is used as the semiconductor device 7. The switching element and the diode may be connected in reverse parallel to each other. As the semiconductor device 7, an RC (reverse conducting)-IGBT element obtained by integrating an IGBT and an FWD, a power MOSFET element, or an RB (reverse blocking)-IGBT having a sufficient voltage resistance to a reverse bias, for example, may be used.

A shape, the number of arrangements, and an arrangement position, and the like of the semiconductor device 7 are appropriately changeable. Although the semiconductor device 7 in the present embodiment is a vertical switching element obtained by forming functional elements such as transistors on a semiconductor substrate, the semiconductor device 7 is not limited to this, but may be a horizontal switching element.

An upper surface electrode of the semiconductor device 7 is conductively connected to the predetermined circuit board 62 via a metal wiring board 10. The metal wiring board 10 is formed by being bent through press working or the like using a metal material such as a copper material, a copper alloy-based material, an aluminum alloy-based material, or an iron alloy-based material. For example, the semiconductor device 7 and the metal wiring board 10 are bonded to each other with a bonding material such as a solder. The metal wiring board 10 may also be referred to as a lead frame. Another connection member such as a conductor wire may be arranged instead of the metal wiring board 10.

The case member 4 is bonded to a base plate of the cooler (not illustrated) with an adhesive, for example, interposed therebetween. The case member 4 is formed into a rectangular frame shape having an opening section 4a at its center. The three unit modules 2, described above, are housed in the opening section 4a having a rectangular shape. That is, the three unit modules 2 are housed in a space to be defined by the frame-shaped case member 4.

The case member 4 is provided with a main terminal (a P terminal 16, an N terminal 17, and an M terminal 18) for external connection and a control terminal 19 for control as an example of a terminal member. Recesses 42 and 43 each having a square shape in a planar view are formed on a wall section 40 positioned on the negative side in the Y-direction in a pair of wall sections 40 and 41 opposing each other in the transverse direction (the Y-direction) of the case member 4.

The P terminal 16 (a nut section 16a, described below) is arranged in the recess 42. One P terminal 16 is arranged for each of the unit modules 2. The P terminal 16 is connected to the insulating substrate 6 (the predetermined circuit board 62) via an ultrasonic bonding section (not illustrated).

The P terminal 16 is formed by integrally molding the nut section 16a and a connection terminal 16b. The nut section 16a is formed of a square nut having a predetermined thickness. The nut section 16a has a screw hole 16c penetrating therethrough in the thickness direction formed at its center. The nut section 16a is provided on the side of one end (proximal end) of the connection terminal 16b. A shape of the nut section 16a is appropriately changeable.

Similarly, the N terminal 17 (a nut section 17a, described below) is arranged in the recess 43. One N terminal 17 is arranged for each of the unit modules 2. The N terminal 17 is connected to the insulating substrate 6 (the predetermined circuit board 62) via an ultrasonic bonding section (not illustrated).

The N terminal 17 is formed by integrally molding the nut section 17a and a connection terminal 17b. The nut section 17a is formed of a square nut having a predetermined thickness. The nut section 17a has a screw hole 17c penetrating therethrough in the thickness direction formed at its center. The nut section 17a is provided on the side of one end (proximal end) of the connection terminal 17b. A shape of the nut section 17a is appropriately changeable.

A recess 44 having a square shape in a planar view is formed on the wall section 41 on the positive side in the Y-direction in the pair of wall sections 40 and 41 opposing each other in the transverse direction (the Y-direction) of the case member 4. The M terminal 18 (a nut section 18a, described below) is arranged in the recess 44. One M terminal 18 is arranged for each of the unit modules 2. An end portion (a connection terminal 18b) of the M terminal 18 is connected to the insulating substrate 6 (the predetermined circuit board 62) via an ultrasonic bonding section 21a illustrated in FIG. 2.

The M terminal 18 is formed by integrally molding the nut section 18a and the connection terminal 18b, described below. The nut section 18a is formed of a square nut having a predetermined thickness. The nut section 18a has a screw hole 18c penetrating therethrough in the thickness direction formed at its center. The nut section 18a is provided on the side of one end (proximal end) of the connection terminal 18b. A shape of the nut section 18a is appropriately changeable.

The P terminal 16, the N terminal 17, and the M terminal 18, described above, may be respectively referred to as a positive electrode terminal (input terminal), a negative electrode terminal (output terminal), and an intermediate terminal (output terminal). Respective one ends (the nut sections 16a, 17a, and 18a) of the P terminal 16, the N terminal 17, and the M terminal 18 constitute a main terminal connectable to an external conductor, and respective other ends (the connection terminals 16b, 17b, and 18b) of the P terminal 16, the N terminal 17, and the M terminal 18 are bonded to the predetermined circuit board 62 of the insulating substrate 6 via an ultrasonic bonding section, described below.

Each of the connection terminals 16b, 17b, and 18b is formed of a metal material such as a copper material, a copper alloy-based material, an aluminum alloy-based material, or an iron alloy-based material. A shape, an arrangement position, and the number of arrangements, for example, of each of the terminals are not limited to the foregoing, but are appropriately changeable.

The control terminal 19 is provided in the wall section 41 on the positive side in the Y-direction. A plurality of (e.g., ten) control terminals 19 are arranged for each of the unit modules 2. More specifically, in one unit module 2, ten control terminals 19, i.e., five control terminals 19 and five control terminals 19 are arranged with the M terminal 18 sandwiched therebetween in the left-right direction (X-direction). The ten control terminals are arranged along the outer periphery of the opening section 4a. A shape, an arrangement position, and the number of arrangements of the control terminal 19 are not limited to these, but are appropriately changeable.

A pair of pillar sections 41a vertically protruding in the Z-direction from an upper surface of the wall section 41 along the opening section 4a is formed at an edge of the wall section 41. The pair of pillar sections 41a is arranged such that the M terminal 18 is sandwiched therebetween. A stepped section 41b lowered by one step from the upper surface of the wall section 41 is formed along the opening section 4a on the inner side (the negative side in the Y-direction) of each of the pillar sections 41a. The stepped sections 41b are also arranged in a pair for each of the unit modules 2 such that the M terminal 18 is sandwiched therebetween in the left-right direction (X-direction).

Each of the control terminals 19 is formed of a metal material such as a copper material, a copper alloy-based material, an aluminum alloy-based material, or an iron alloy-based material. The control terminal 19 is integrally molded (insert-molded) to be embedded in the case member 4.

More specifically, the five control terminals 19 are embedded in the stepped section 41b corresponding to the one pillar section 41a. Each of the control terminals 19 has a substantially L shape in cross section cut along a YZ plane. The control terminal 19 has an inner terminal section 19a (one end portion) to be connected to the inner semiconductor device 7 and an outer terminal section 19b (the other end portion) for external connection. The control terminal 19 is formed into an L shape in a side view by connecting the inner terminal section 19a and the outer terminal section 19b to each other.

The inner terminal section 19a as one end side of the control terminal 19 has a flat plate shape along a planar direction of the semiconductor device 7. The inner terminal section 19a extends inward in the Y-direction from an inner side surface of the case member 4 (the opening section 4a). The inner terminal section 19a has a predetermined thickness in the Z-direction.

A large portion excluding an upper surface of the inner terminal section 19a is embedded in the stepped section 41b. The upper surface of the inner terminal section 19a is coplanar with an upper surface of the stepped section 41b. That is, the upper surface of the inner terminal section 19a is exposed to the stepped section 41b and is a connection portion (bonding point) of a wiring member W (a bonding wire). The inner terminal section 19a may also be referred to as a bonding pad. The inner terminal section 19a is connected to the upper surface electrode of the semiconductor device 7 via the wiring member W (that may also be referred to as a control wiring).

A plurality of projections 41c for enhancing adhesion to sealing resin are formed on an inner side surface of the opening section 4a between the pillar section 41a and the stepped section 41b. A positioning section 41d having a convex shape to be a target point at the time of bonding is formed on the upper surface of the stepped section 41b.

The case member 4 has a plurality of through holes 4b formed along its outer peripheral edge. Each of the through holes 4b is a hole into which a screw (not illustrated) for fixing the semiconductor apparatus 1 is to be inserted. The through hole 4b penetrates the case member 4 up to the base plate of the cooler.

Resin for the case member 4 can be selected from insulating resin such as polybutylene terephthalate (PBT), polybutyl acrylate (PBA), polyamide (PA), acrylonitrile-butadiene-styrene (ABS), liquid crystal polymer (LCP), polyetheretherketone (PEEK), polybutylene succinate (PBS), urethane, and silicon in addition to polyphenylene sulfide (PPS). Resin to be selected may be a mixture of two or more types of resin. A filler (e.g., a glass filler) for improving strength or functionality may be contained in resin.

A conductor wire (bonding wire) is used for the wiring member W. As a material for the conductor wire, any one of gold, copper, aluminum, a gold alloy, a copper alloy, and an aluminum alloy or their combination can be used. A member other than the conductor wire can also be used as the wiring member. For example, a ribbon can be used as the wiring member.

An internal space to be defined by the frame-shaped case member 4 is filled with sealing resin (not illustrated). That is, the insulating substrate 6 and the semiconductor device 7 mounted thereon are thus sealed into the above-described space. The case member 4 defines a space that houses the plurality of unit modules 2 (the insulating substrates 6 and the semiconductor devices 7) and sealing resin.

The sealing resin is composed of thermosetting resin. The sealing resin preferably contains at least one of epoxy, silicone, urethane, polyimide, polyamide, and polyamide-imide. Epoxy resin in which a filler is mixed, for example, is preferable for the sealing resin in terms of insulation, heat resistance, and heat dissipation.

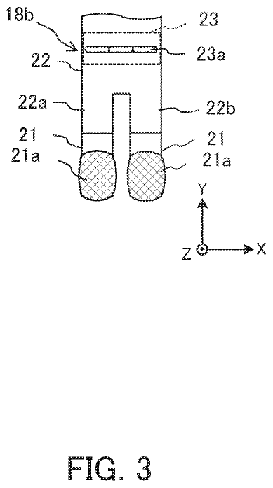

Then, the connection terminal 18b in the M terminal 18 will be described with reference to FIGS. 2 and 3.

FIGS. 2 and 3 are respectively a right side view and a plan view illustrating the connection terminal 18b.

As illustrated in FIG. 2, the connection terminal 18b has a distal end portion 21 to be bonded to the insulating substrate 6 (the circuit board 62), a main body portion 22 that rises from the distal end portion 21 and extends toward the main terminal (the nut section 18a) (toward the positive side in the Y-direction), and a coupling portion 23 having a conductive property and coupled to the main body portion 22.

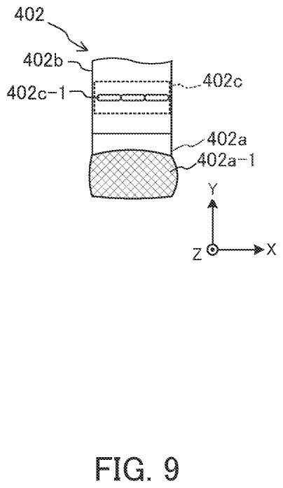

As illustrated in FIG. 3, the connection terminal 18b has two distal end portions 21, and the main body portion 22 includes two branch sections 22a and 22b obtained by branching toward the two distal end portions 21. The distal end portions 21 are bonded to the circuit board 62 by respective ultrasonic bonding sections 21a. The main body portion 22 branches into the plurality of branch sections 22a and 22b, thereby making ultrasonic bonding easy. Three or more distal end portions 21 may be provided. Alternatively, only one distal end portion 21 may be provided, as illustrated in FIG. 9 (a fourth modification), described below. When a plurality of distal end portions 21 are provided, the main body portion 22 may include the same number of branch sections 22a and 22b as that of the distal end portions 21.

As indicated by a broken line (a hidden line because the coupling portion 23 is positioned while being hidden below the main body portion 22) in the plan view of FIG. 3, the coupling portion 23 is coupled to the main body portion 22 on a lower surface of the main body portion 22.

The coupling portion 23 is provided separately from the main body portion 22, and is coupled to the main body portion 22 by laser welding (a laser welding section 23a) from above the main body portion 22, for example. When the coupling portion 23 is thus provided separately from the main body portion 22, the existing connection terminal 18b (an entire portion excluding the coupling portion 23) can be used. This can more prevent an unexpected crack from occurring and prevent a load on the case member 4 or the like that supports the connection terminal 18b from unexpectedly increasing at the time of ultrasonic bonding or the like in the ultrasonic bonding sections 21a, for example, with changes in shape than in a manner in which a shape of the connection terminal 18b is changed to integrally provide the coupling portion 23.

As illustrated in FIG. 2, the coupling portion 23 is positioned to be spaced in the Y-direction apart from a rising portion of the main body portion 22, for example. Accordingly, a current path of the connection terminal 18b (a direction in which the connection terminal 18b extends) is divided into the main body portion 22 (the branch sections 22a and 22b) and the coupling portion 23, thereby making it easy for a high-frequency current or the like to flow, for example. Moreover, it can be considered that the surface area of the connection terminal 18b more increases to increase heat dissipation than when the coupling portion 23 is not spaced apart from the rising portion. The coupling portion 23 may be formed of the same material as a material for the main body portion 22, i.e., a metal material such as a copper material, a copper alloy-based material, an aluminum alloy-based material, or an iron alloy-based material. The coupling portion 23 may be provided integrally with the main body portion 22 by processing such as cutting, for example.

A lower end of the coupling portion 23 may be bonded to the insulating substrate 6 (the circuit board 62) with a bonding material S such as a solder interposed therebetween. The order of bonding is bonding of the coupling portion 23 to the main body portion 22 (e.g., bonding by laser welding), bonding of the coupling portion 23 to the insulating substrate 6 (the circuit board 62) (e.g., bonding using the bonding material S), and bonding of the distal end portion 21 to the insulating substrate 6 (the circuit board 62) (e.g., bonding by ultrasonic bonding), although an example. If the distal end portion 21 is ultrasonically bonded to the insulating substrate 6 after the coupling portion 23 is thus bonded to the insulating substrate 6, the coupling portion 23 can support the main body portion 22. Accordingly, a load on the case member 4 or the like at the time of ultrasonic bonding of the distal end portion 21 to the insulating substrate 6 can be reduced.

The coupling portion 23 is provided such that a cross-sectional area (an XY plane) perpendicular to a current path (the Z-direction) of the coupling portion 23 is larger than a cross-sectional area (an XZ plane) perpendicular to a current path (the Y-direction) of a portion (main body coupling portion), to which the coupling portion 23 is coupled, of the main body portion 22. As a result, even if the volume of the connection terminal 18b is reduced when the connection terminal 18b is bonded to the insulating substrate 6 in a narrow space and when the main body portion 22 branches into a plurality of portions (e.g., the branch sections 22a and 22b), for example, the volume of the connection terminal 18b can be increased by the coupling portion 23. Accordingly, the thermal capacity of the connection terminal 18b can be increased. An example of a manner in which the cross-sectional area (the XY plane) perpendicular to the current path (the Z-direction) of the coupling portion 23 is larger than the cross-sectional area (the XZ plane) perpendicular to the current path (the Y-direction) of the portion, to which the coupling portion 23 is coupled, of the main body portion 22 is a case where a plate thickness t2 (a width in a YZ plane: approximately 2.0 mm to 3.0 mm as an example) of the coupling portion 23 is larger than a plate thickness t1 (the entirety, excluding the coupling portion 23, of the connection terminal 18b has a constant plate thickness: 1.0 mm to 1.5 mm as an example) of the main body portion 22. In this case, a width in the X-direction of the coupling portion 23 may be not more than a width in the X-direction of the main body portion 22. Alternatively, when the width in the X-direction of the coupling portion 23 is not less than the width in the X-direction of the main body portion 22, the plate thickness t2 of the coupling portion 23 may be not more than the plate thickness t1 of the main body portion 22. The coupling portion 23 can have any shape such as a plate shape, a block shape, a columnar shape, and a polygonal columnar shape. The coupling portion 23 may be separated into a plurality of portions.

Then, first to fourth modifications of the present embodiment will be described.

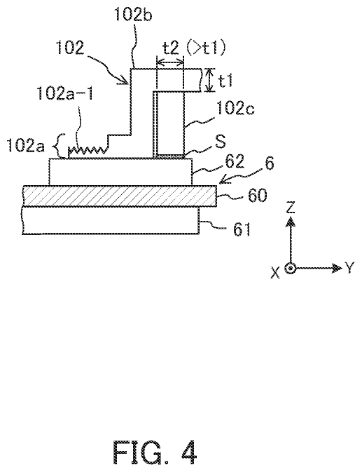

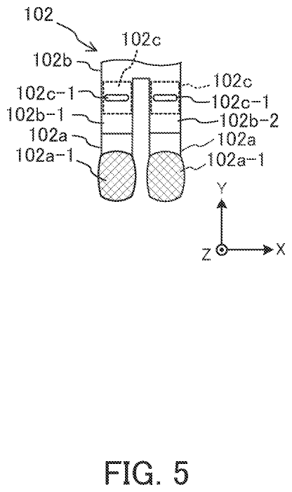

FIGS. 4 and 5 are respectively a right side view and a plan view illustrating a connection terminal 102 in the first modification.

The connection terminal 102 in the first modification differs from the connection terminal 18b illustrated in FIGS. 2 and 3 only in that there are provided a plurality of (e.g., two) coupling portions 102c separately provided and coupling positions of the coupling portions 102c to a main body portion 102b are branch sections 102b-1 and 102b-2. Accordingly, the coupling portions 102c will be mainly described, and description will be omitted for distal end portions 102a (ultrasonic bonding sections 102a-1), a main body portion 102b (the branch sections 102b-1 and 102b-2), and laser welding sections 102c-1 in the connection terminal 102, which can be respectively made the same as the distal end portions 21 (the ultrasonic bonding sections 21a), the main body portion 22 (the branch sections 22a and 22b), and the laser welding section 23a in the connection terminal 18b.

As illustrated in FIG. 4, the distal end portions 102a in the connection terminal 102 are bonded to a circuit board 62 by the respective ultrasonic bonding sections 102a-1. In the main body portion 102b, the two coupling portions 102c are respectively coupled to the branch sections 102b-1 and 102b-2 on lower surfaces of the branch sections 102b-1 and 102b-2, as indicated by broken lines (hidden lines because the coupling portions 102c are positioned while being hidden below the branch sections 102b-1 and 102b-2) in the plan view of FIG. 5. The plurality of coupling portions 102c may be coupled to the main body portion 102b, in portions other than the branch sections 102b-1 and 102b-2.

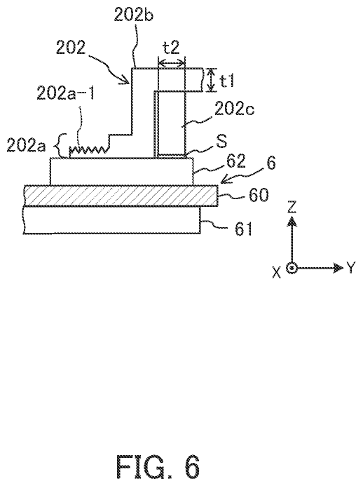

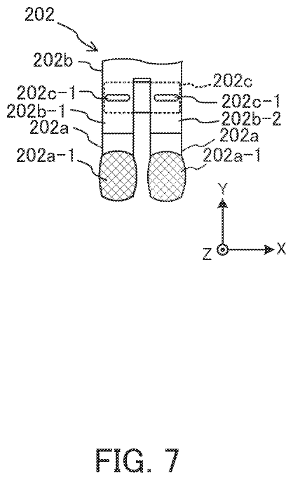

FIGS. 6 and 7 are respectively a right side view and a plan view illustrating a connection terminal 202 in a second modification.

The connection terminal 202 in the second modification differs from the connection terminal 102 illustrated in FIGS. 4 and 5 only in a coupling portion 202c. Accordingly, the coupling portion 202c will be mainly described, and description will be omitted for distal end portions 202a (ultrasonic bonding sections 202a-1), a main body portion 202b (branch sections 202b-1 and 202b-2), and laser welding sections 202c-1 in the connection terminal 202, which can be respectively made the same as the distal end portions 102a (the ultrasonic bonding sections 102a-1), the main body portion 102b (the branch sections 102b-1 and 102b-2), and the laser welding sections 102c-1 in the connection terminal 102.

As illustrated in FIG. 7, the connection terminal 202 has the single coupling portion 202c, and the coupling portion 202c is provided over the plurality of (e.g., two) branch sections 202b-1 and 202b-2, and is coupled to each of the two branch sections 202b-1 and 202b-2. As a method for coupling the coupling portion 202c to the branch sections 202b-1 and 202b-2, bonding by laser welding, for example, can be adopted, like in the foregoing description.

As a result, a width in the X-direction of the coupling portion 202c is larger than a total width in the X-direction of the two branch sections 202b-1 and 202b-2. Also in the modification, a plate thickness t2 (a width in a YZ plane) of the coupling portion 202c is larger than a plate thickness t1 of the main body portion 202b (the entirety, excluding the coupling portion 202c, of the connection terminal 202 has a constant plate thickness), as illustrated in FIG. 6. Even if the plate thickness t2 of the coupling portion 202c (the branch sections 202b-1 and 202b-2) is not more than the plate thickness t1 of the main body portion 202b, when the width in the X-direction of the coupling portion 202c is larger than a total width in the X-direction of the two branch sections 202b-1 and 202b-2, as described above, a cross-sectional area (an XY plane) perpendicular to a current path (the Z-direction) of the coupling portion 202c can be made larger than a total of cross-sectional areas (an XZ plane) perpendicular to a current path (the Y-direction) of a portion (the branch sections 202b-1 and 202b-2) to which the coupling portion 202c is coupled, in the main body portion 202b.

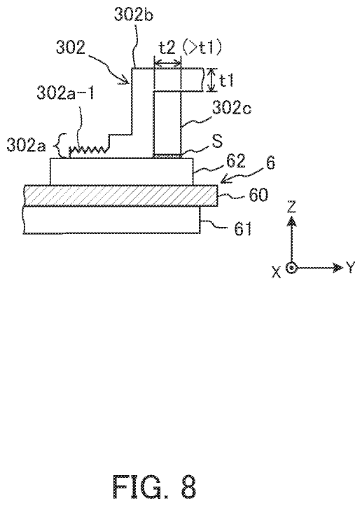

FIG. 8 is a right side view illustrating a connection terminal 302 in a third modification.

The connection terminal 302 in the third modification can be made the same as the connection terminal 18b (the one coupling portion 23) illustrated in FIGS. 2 and 3 or the connection terminal 102 (the two coupling portions 102c) illustrated in FIGS. 4 and 5 except for a coupling portion 302c. Accordingly, the coupling portion 302c will be mainly described, and description will be omitted for a distal end portion 302a (an ultrasonic bonding section 302a-1) and a main body portion 302b in the connection terminal 302, which can be respectively made the same as the distal end portion 102a (the ultrasonic bonding section 102a-1) and the main body portion 102b in the connection terminal 102. The connection terminal 302 may have similar branch sections to the above-described branch sections 102b-1 and 102b-2 in the connection terminal 102 and a similar laser welding section to the above-described laser welding section 102c-1 in the connection terminal 102, although illustration in FIG. 8 is omitted.

The coupling portion 302c in the connection terminal 302 is positioned with no spacing in the Y-direction from a rising portion of the main body portion 302b (e.g., the branch sections). In this case, the coupling portion 302c can more reliably support the main body portion 302b. Accordingly, a load on a case member 4 or the like at the time of ultrasonic bonding of the distal end portion 302a to an insulating substrate 6 can be more reduced. The coupling portion 302c may be bonded in the Y-direction by a bonding material, laser welding, or the like in the rising portion of the main body portion 302b, unlike in the laser welding sections 102c-1 in the connection terminal 102 illustrated in FIG. 5.

FIG. 9 is a plan view illustrating a connection terminal 402 in a fourth modification.

The connection terminal 402 in the fourth modification has a single distal end portion 402a, and a main body portion 402b does not branch. Accordingly, the distal end portion 402a and the main body portion 402b will be mainly described, and detailed description is omitted for an ultrasonic bonding section 402a-1 in the connection terminal 402 that can be made the same as the ultrasonic bonding sections 21a in the connection terminal 18b illustrated in FIGS. 2 and 3 and the ultrasonic bonding sections 202a-1 in the connection terminal 202 illustrated in FIG. 7 and a coupling portion 402c (a laser welding section 402c-1) in the connection terminal 402 that can be made the same as the coupling portion 23 (the laser welding section 23a) in the connection terminal 18b illustrated in FIG. 3.

The connection terminal 402 has the single distal end portion 402a. Accordingly, the main body portion 402b does not branch into a plurality of portions (has no branch sections). A width in the X-direction of the single coupling portion 402c is the same as a width in the X-direction of the main body portion 402b, for example. A plate thickness t2 (not illustrated) (a width in a YZ plane) of the coupling portion 402c is larger than a plate thickness t1 (not illustrated) of the main body portion 402b (the entirety, excluding the coupling portion 402c, of the connection terminal 402 has a constant plate thickness), for example. Accordingly, it can be said that a cross-sectional area (an XY plane) perpendicular to a current path (the Z-direction) of the coupling portion 402c is larger than a cross-sectional area (an XZ plane) perpendicular to a current path (the Y-direction) of a portion, to which the coupling portion 402c is coupled, of the main body portion 402b. If the plate thickness t2 (not illustrated) of the coupling portion 402c is larger than the plate thickness t1 (not illustrated) of the main body portion 402b, the width in the X-direction of the coupling portion 402c may be not more than the width in the X-direction of the main body portion 402b. Alternatively, if the width in the X-direction of the coupling portion 402c is not less than the width in the X-direction of the main body portion 402b, the plate thickness t2 of the coupling portion 402c may be not more than the plate thickness t1 of the main body portion 402b. The coupling portion 402c may be separated into a plurality of portions.

Although the connection terminal 18b (102, 202, 302, 402) that tends to have the highest temperature among the connection terminal 16b of the P terminal 16, the connection terminal 17b of the N terminal 17, and the connection terminal 18b of the M terminal 18 has been described as an example in the foregoing description, the connection terminals 16b and 17b may each have a similar configuration to that of the connection terminal 18b (102, 202, 302, 402). Although the semiconductor apparatus 1 has a total of three unit modules 2 in a U phase, a V phase, and a W phase in the foregoing description, the semiconductor apparatus 1 may have a single unit module 2.

In the present embodiment described above, a semiconductor apparatus 1 includes a semiconductor device 7, an insulating substrate 6 having a circuit board 62 to be electrically connected to the semiconductor device 7, and an M terminal 18 as an example of a terminal member. The M terminal 18 has a main terminal (a nut section 18a) connectable to an external conductor and a connection terminal 18b to be bonded to the insulating substrate 6 (the circuit board 62). The connection terminal 18b has a distal end portion 21 to be bonded to the circuit board 62, a main body portion 22 that rises from the distal end portion 21 and extends toward the main terminal (the nut section 18a), and a coupling portion 23 having a conductive property and coupled to the main body portion 22. The coupling portion 23 has a larger cross-sectional area perpendicular to a current path than that of a portion, to which the coupling portion 23 is coupled, of the main body portion 22.

When the coupling portion 23 having a larger cross-sectional area perpendicular to the current path than that of the portion, to which the coupling portion 23 is coupled, of the connection terminal 18b (the main body portion 22) is thus provided, the volume of the connection terminal 18b can be increased by the coupling portion 23 even if the volume of the connection terminal 18b is reduced when the connection terminal 18b is bonded to the circuit board 62 in a narrow space or when the main body portion 22 branches into a plurality of portions (e.g., branch sections 22a and 22b), for example. Accordingly, the thermal capacity of the connection terminal 18b can be increased. Therefore, according to the present embodiment, in the terminal member (e.g., the M terminal 18) having the main terminal (the nut section 18a) connectable to the external conductor and the connection terminal 18b to be bonded to the insulating substrate 6, the connection terminal 18b can be prevented from generating heat. The connection terminal 18b can be thus prevented from generating heat, thereby making it possible to avoid deteriorating the reliability of the semiconductor apparatus 1 due to a thermal stress of the connection terminal 18b.

In the present embodiment, the connection terminal 18b has a plurality of (e.g., two) distal end portions 21, as illustrated in FIG. 3. The main body portion 22 includes two branch sections 22a and 22b obtained by branching toward the two distal end portions 21.

Accordingly, when the main body portion 22 branches into the branch sections 22a and 22b in consideration of ease of ultrasonic bonding in an ultrasonic bonding section 21a, for example, the volume of the connection terminal 18b can be increased by the coupling portion 23 even if the volume of the connection terminal 18b is reduced. Accordingly, the thermal capacity of the connection terminal 18b can be increased.

In the first modification of the present embodiment, a connection terminal 102 has a plurality of coupling portions 102c separately provided.

Accordingly, the plurality of coupling portions 102c can be coupled to different portions of a main body portion 102b to match an arrangement space of the connection terminal 102. Alternatively, the main body portion 102b can be supported by the coupling portions 102c in the different portions of the main body portion 102b.

In the present embodiment, a plate thickness t2 of the coupling portion 23 is larger than a plate thickness t1 of the main body portion 22.

As a result, a simple configuration in which the plate thickness t2 of the coupling portion 23 is larger than the plate thickness t1 of the main body portion 22 makes it possible to increase the cross-sectional area perpendicular to the current path of the coupling portion 23 and increase the thermal capacity of the connection terminal 18b.

In the present embodiment, the coupling portion 23 is bonded to the insulating substrate 6 (the circuit board 62) by a bonding material S (or another bonding method), for example.

As a result, when the coupling portion 23 is bonded to the circuit board 62 in the insulating substrate 6, a current can be caused to flow between the coupling portion 23 and the insulating substrate 6 (the circuit board 62), and the main body portion 22 can be more reliably supported by the coupling portion 23.

In the present embodiment, a method for manufacturing a semiconductor apparatus 1 is a method for manufacturing the above-described semiconductor apparatus 1, the coupling portion 23 is coupled to the main body portion 22, for example by laser welding (a laser welding section 23a), the coupling portion 23 that remains coupled to the main body portion 22 is bonded to the insulating substrate 6, and the distal end portion 21 in the connection terminal 18b with the coupling portion 23 bonded to the insulating substrate 6 is bonded (e.g., ultrasonically bonded) to the circuit board 62.

As a result, when the connection terminal 18b (the distal end portion 21) is bonded to the circuit board 62, the coupling portion 23 can support the main body portion 22. Accordingly, a load on the case member 4 or the like can be reduced. Before the distal end portion 21 in the connection terminal 18b is bonded to the circuit board 62, the coupling portion 23 can be coupled to the main body portion 22 by processing from above the main body portion 22, for example. Accordingly, the connection terminal 18b can be easily processed.

The invention described in the original claims of the present application is noted below.

### <Note 1>

A semiconductor apparatus comprising:
a semiconductor device;
an insulating substrate having a circuit board to be electrically connected to the semiconductor device; and
a terminal member having a main terminal connectable to an external conductor and a connection terminal to be bonded to the circuit board, wherein
the connection terminal has at least one distal end portion to be bonded to the circuit board, a main body portion that rises from the at least one distal end portion and extends toward the main terminal, and at least one coupling portion having a conductive property and coupled to the main body portion, and
the at least one coupling portion has a larger cross-sectional area perpendicular to a current path than that of a portion, to which the at least one coupling portion is coupled, of the main body portion.

### <Note 2>

The semiconductor apparatus described in the note 1, wherein
the at least one distal end portion comprises a plurality of distal end portions,
the connection terminal has the plurality of distal end portions, and
the main body portion includes a plurality of branch sections obtained by branching toward the plurality of distal end portions.

### <Note 3>

The semiconductor apparatus described in the note 1, wherein
the at least one coupling portion comprises a plurality of coupling portions, and
the connection terminal has the plurality of coupling portions separately provided.

### <Note 4>

The semiconductor apparatus described in the note 1, wherein
a plate thickness of the at least one coupling portion is larger than a plate thickness of the main body portion.

### <Note 5>

The semiconductor apparatus described in the note 1, wherein
the at least one coupling portion is bonded to the circuit board.

### <Note 6>

A method for manufacturing a semiconductor apparatus comprising a semiconductor device, an insulating substrate having a circuit board to be electrically connected to the semiconductor device, and a terminal member having a main terminal connectable to an external conductor and a connection terminal to be bonded to the circuit board, the connection terminal having a distal end portion to be bonded to the circuit board, a main body portion that rises from the distal end portion and extends toward the main terminal, and a coupling portion having a conductive property and coupled to the main body portion, the coupling portion having a larger cross-sectional area perpendicular to a current path than that of a portion, to which the coupling portion is coupled, of the main body portion, the method comprising:
coupling the coupling portion to the main body portion;
bonding the coupling portion that remains coupled to the main body portion to the circuit board; and
bonding the distal end portion of the connection terminal with the coupling portion bonded to the circuit board to the circuit board.

As described above, the present invention produces an effect of being able to prevent a connection terminal in a terminal member from generating heat, and is useful for a power semiconductor apparatus, for example.

### REFERENCE SIGNS LIST

1: semiconductor apparatus
2: unit module
4: case member
4a: opening section
4b: through hole
6: insulating substrate
7: semiconductor device
10: metal wiring board (lead frame)
16: P terminal
16a: nut section
16b: connection terminal
16c: screw hole
17: N terminal
17a: nut section
17b: connection terminal
17c: screw hole
18: M terminal
18a: nut section
18b: connection terminal
18c: screw hole
19: control terminal
19a: inner terminal section (bonding pad)
19b: outer terminal section
21: distal end portion
21a: ultrasonic bonding section
22: main body portion
22a, 22b: branch section
23: coupling portion
23a: laser welding section
40: wall section
41: wall section
41a: pillar section
41b: stepped section
41c: projection
41d: positioning section
42, 43, 44: recess
60: insulating plate
61: heat dissipation plate
62: circuit board
102, 202, 302, 402: connection terminal
102a, 202a, 302a, 402a: distal end portion
102a-1, 202a-1, 302a-1, 402a-1: ultrasonic bonding section
102b, 202b, 302b, 402b: main body portion
102b-1, 102b-2, 202b-1, 202b-2: branch section
102c, 202c, 302c, 402c: coupling portion
102c-1, 202c-1, 402c-1: laser welding section
S: bonding material
W: wiring member

What is claimed is:

1. A semiconductor apparatus, comprising:
a semiconductor device;
an insulating substrate including a circuit board that is electrically connected to the semiconductor device; and
a terminal member having a main terminal connectable to an external conductor and a connection terminal bonded to the circuit board, wherein
the connection terminal has
at least one distal end portion bonded to the circuit board,
a main body portion that rises from the at least one distal end portion and extends toward the main terminal, and
a coupling portion that has a conductive property and is coupled to the main body portion,
the main body portion has a main body coupling portion to which the coupling portion is coupled,
a cross-sectional area of the coupling portion perpendicular to a direction in which a current flows in the coupling portion is larger than a cross-sectional area of the main body coupling portion perpendicular to a direction in which a current flows in the main body coupling portion.

2. The semiconductor apparatus according to claim 1, wherein
the at least one distal end portion includes a plurality of distal end portions, and
the main body portion further includes a plurality of branch sections respectively branching toward respective ones of the plurality of distal end portions.

3. The semiconductor apparatus according to claim 1, wherein
the coupling portion is provided in plurality, and the coupling portions of the plurality of coupling portions are separate from one another.

4. The semiconductor apparatus according to claim 1, wherein
the coupling portion and the main body portion each have a plate shape,
a thickness of the coupling portion perpendicular to the direction in which the current flows in the coupling portion is larger than a thickness of the main body portion perpendicular to a direction in which a current flows in the main body portion.

5. The semiconductor apparatus according to claim 1, wherein
the coupling portion is bonded to the circuit board.

6. A method for manufacturing a semiconductor apparatus comprising a semiconductor device, an insulating substrate having a circuit board that is electrically connected to the semiconductor device, and a terminal member having a main terminal connectable to an external conductor and a connection terminal to be bonded to the circuit board, the connection terminal having a distal end portion to be bonded to the circuit board, a main body portion that rises from the distal end portion and extends toward the main terminal, and a coupling portion that has a conductive property and is coupled to the main body portion, the main body portion having a main body coupling portion to which the coupling portion is to be coupled, a cross-sectional area of the coupling portion perpendicular to a direction in which a current flows in the coupling portion being larger than a cross-sectional area of a main body coupling portion perpendicular to a direction in which a current flows in the main body coupling portion, the method comprising:
coupling the coupling portion to the main body coupling portion of the main body portion;
bonding the coupling portion that remains coupled to the main body portion to the circuit board; and
bonding the distal end portion of the connection terminal with the coupling portion bonded to the circuit board to the circuit board.
